(19) United States
(12) Patent Application Publication
(10) Pub. No.: US 2009/0140324 A1
(43) Pub. Date: Jun. 4, 2009

(54) METHOD OF MANUFACTURING FLASH MEMORY DEVICE

(76) Inventor: Jin-Ha Park, Echeon-si (KR)

Correspondence Address: SHERR & VAUGHN, PLLC, 620 HERNDON PARKWAY, SUITE 200, HERNDON, VA, 20170, US

(21) Appl. No.: 12/325,160

(22) Filed: Nov. 29, 2008

(30) Foreign Application Priority Data
Nov. 29, 2007 (KR) 10-2007-0122672

(51) Int. Cl. H01L 29/423; H01L 21/336

(52) U.S. Cl. 257/324; 438/287; 257/E29.132

(57) ABSTRACT

A method of manufacturing a flash memory device and a flash memory device in which a tunnel oxide layer and a first polysilicon pattern are formed on and/or over a semiconductor substrate. A second polysilicon pattern and a third polysilicon pattern are formed on and/or over a sidewall of the first polysilicon pattern and a dielectric layer and a polysilicon layer formed on and/or over the first, second and third polysilicon patterns. An etching process is performed to form a tunnel oxide layer pattern, a dielectric pattern, and a fourth polysilicon pattern.

The present application claims priority under 35 U.S.C. §119 to Korean Patent Application No. 10-2007-0122672 (filed on Nov. 29, 2007), which is hereby incorporated by reference in its entirety.

### BACKGROUND

A flash memory device is a type of non-volatile memory which maintains stored data even when power is turned off. It has a comparatively high data processing speed in write, read and delete operations. Accordingly, flash memory devices may be used as data storage devices for BIOS of a personal computer (PC), a set-top box, a printer or a network server. Flash memory devices may also be employed in cameras and cellular phones, etc.

### SUMMARY

In embodiments, a method of manufacturing a flash memory device includes: providing a semiconductor substrate, forming a tunnel oxide layer on and/or over the semiconductor substrate, forming a first polysilicon pattern having sidewalls on and/or over the tunnel oxide layer, forming a second polysilicon pattern on and/or over a sidewall of the first polysilicon pattern, forming a third polysilicon pattern on and/or over a sidewall of the first polysilicon pattern, forming a dielectric layer on and/or over the first, second and third polysilicon patterns, forming a polysilicon layer on and/or over the dielectric layer, and performing an etching process to form a tunnel oxide layer pattern, a dielectric pattern, and a fourth polysilicon pattern.

In embodiments, a flash memory device includes a semiconductor substrate with a tunnel oxide layer pattern on and/or over the semiconductor substrate. A first polysilicon pattern having sidewalls may be formed on and/or over the tunnel oxide layer pattern. A second polysilicon pattern and a third polysilicon pattern may be formed on and/or over a sidewall of the first polysilicon pattern. A dielectric pattern may be formed on and/or over the first, second and third polysilicon patterns. A fourth polysilicon pattern may be formed on and/or over the dielectric layer.

### DRAWINGS

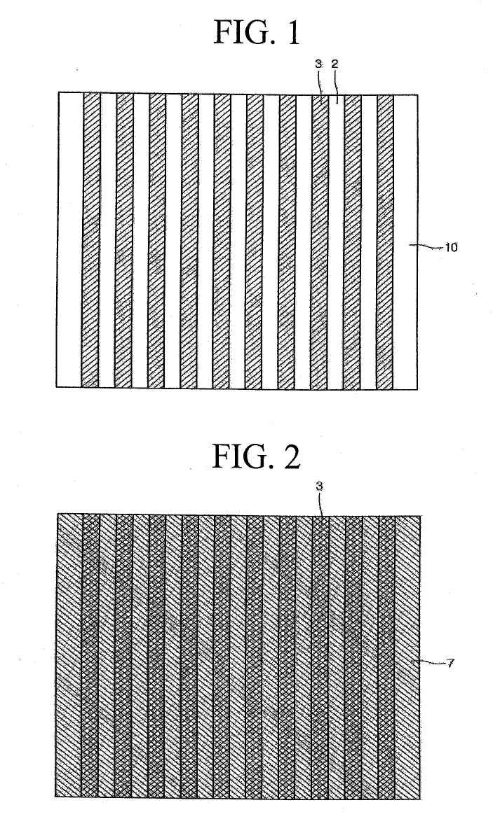

Example FIGS. 1 to 13 illustrate a flash memory device and a method of manufacturing the same in accordance with embodiments.

### DESCRIPTION

Example FIGS. 1 to 11 are plane views and sectional views of a flash memory device according to embodiments.

As shown in example FIG. 1, an active region 3 is defined in a semiconductor substrate 10. The active region 3 may be defined by forming a device isolation layer 2 in the semiconductor substrate 10. The device isolation layer 2 may be formed by forming a trench in the semiconductor substrate 10 and filling the trench with an insulator.

As shown in example FIG. 2, a tunnel oxide layer 13 and a first polysilicon layer 7 may be formed. The tunnel oxide layer 13 may be formed by performing a thermal oxidation process.

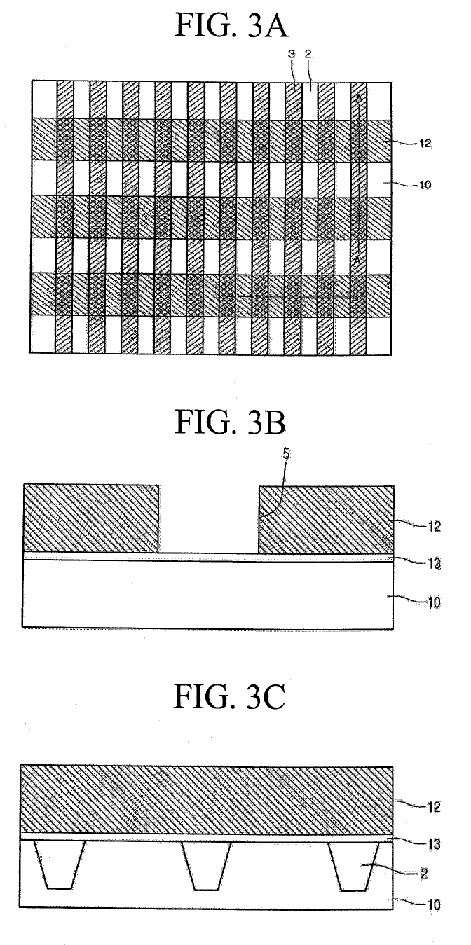

Next, as shown in example FIG. 3A, a first polysilicon pattern 12 maybe formed over the semiconductor substrate 10. The first polysilicon pattern 12 may be formed by patterning the first polysilicon layer 7 to remove a region where a gate is being formed.

Herein, a cross sectional view taken along line A-A′ is shown in example FIG. 3B, and a cross sectional view taken along line B-B′ is shown in example FIG. 3C. As shown in FIG. 3B, a trench 5 may be formed in the first polysilicon pattern 12.

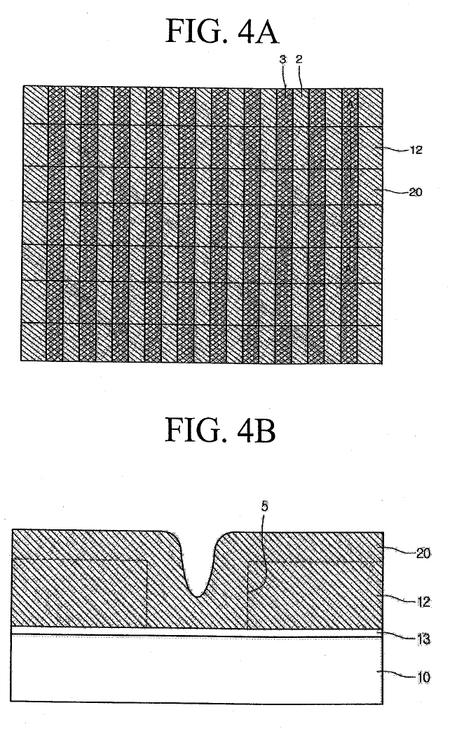

Next, as shown in example FIGS. 4A and 4B, a second polysilicon layer 20 may be formed over the tunnel oxide layer 13 and the first polysilicon pattern 12. The second polysilicon layer 20 may be formed to completely cover the first polysilicon pattern 12.

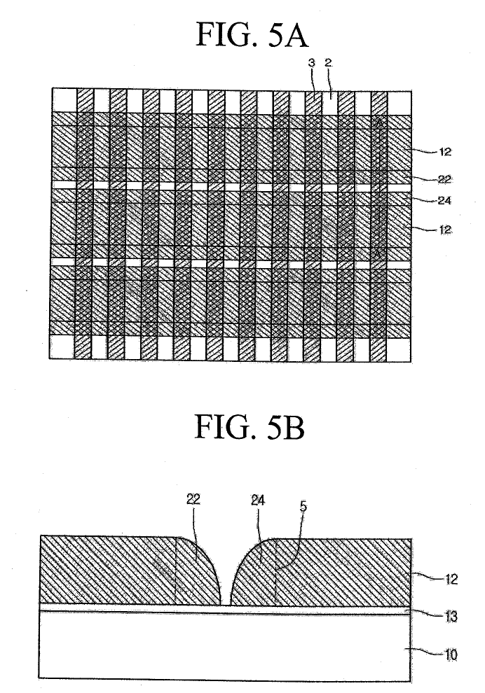

The second polysilicon layer 20 may be anisotropically etched to form a second polysilicon pattern 22 and a third polysilicon pattern 24 as shown in example FIGS. 5A and 5B. Using the anisotropic etch, the second polysilicon pattern 22 and the third polysilicon pattern 24 may be formed at the same time. The second polysilicon pattern 22 and the third polysilicon pattern 24 may be formed over a sidewall of the first polysilicon pattern 12. Some of the tunnel oxide layer 13 may be exposed between the second polysilicon pattern 22 and the third polysilicon pattern 24. The second and third polysilicon patterns 22 and 24 may be floating gates.

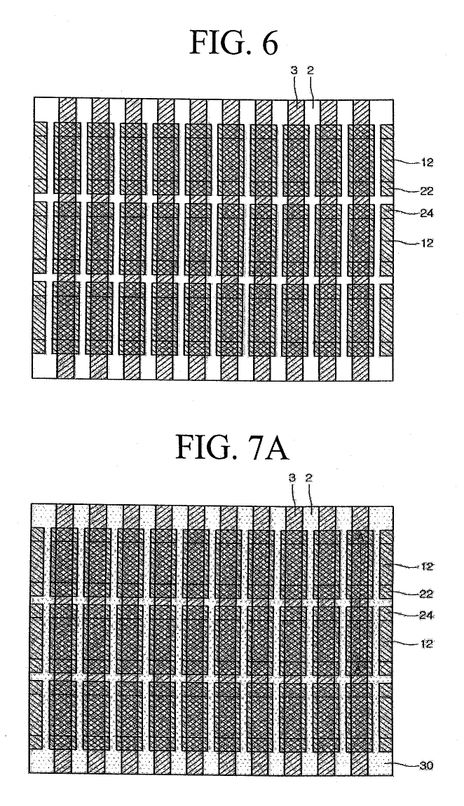

As shown in example FIG. 6, the floating gates may be patterned for isolation between cells. This may be done by patterning the first polysilicon pattern 12. The patterned first polysilicon pattern 12 may be formed over the active region 3.

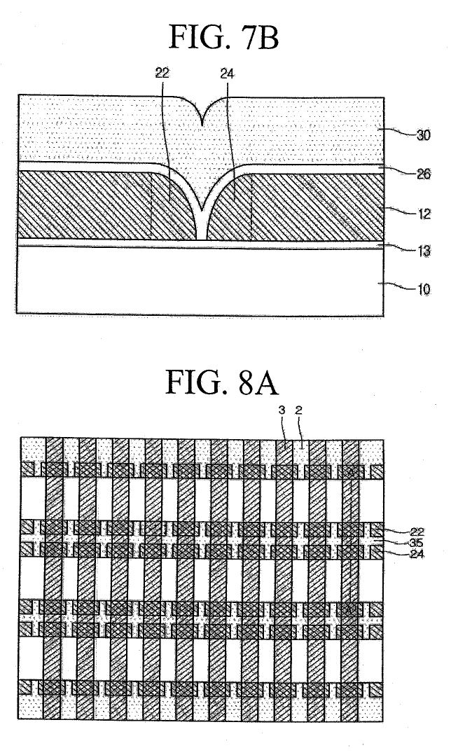

As shown in example FIGS. 7A and 7B, a dielectric layer 26 and a third polysilicon layer 30 may be formed over the first polysilicon pattern 12, the second polysilicon pattern 22 and the third polysilicon pattern 24. The dielectric layer 26 may be formed of an ONO (Oxide-Nitride-Oxide) layer consisting of a first oxide layer, a first nitride layer and a second oxide layer formed in sequence. The dielectric layer 26 may function to insulate an upper layer thereon from a lower layer therebeneath. The dielectric layer 26 may contact the tunnel oxide layer 13 exposed between the second polysilicon pattern 22 and the third polysilicon pattern 24. While embodiments may use an ONO layer as the dielectric layer 26, embodiments are not limited thereto. For example, the dielectric layer 26 may have an ON (Oxide-Nitride) structure consisting of a first oxide layer and a first nitride layer. The third polysilicon layer 30 may form a control gate.

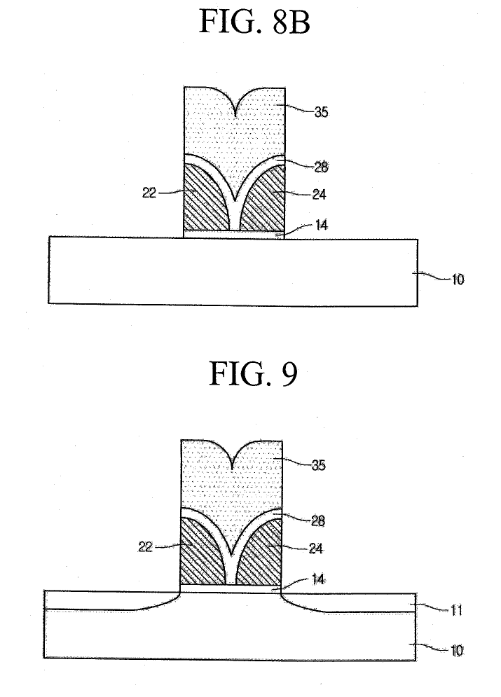

Next, as shown in example FIGS. 8A and 8B, the third polysilicon layer 30, the dielectric layer 26, the first polysilicon pattern 12 and the tunnel oxide layer 13 may be patterned to form a fourth polysilicon pattern 35, a dielectric pattern 28, and a tunnel oxide layer pattern 14. The fourth polysilicon pattern 35, the dielectric pattern 28 and the tunnel oxide layer pattern 14 may be formed by forming a photoresist pattern over the third polysilicon layer 30 and performing an etching process. In the patterning for forming the fourth polysilicon pattern 35, a misalignment may be generated. Although such a misalignment is generated, since the first polysilicon pattern 12 exists over side surfaces of the second and third polysilicon patterns 22 and 24 formed under the fourth polysilicon pattern 35, the fourth polysilicon pattern 35 aligns with the second and third polysilicon patterns 22 and 24. Accordingly, since the same bias may be applied to the second polysilicon pattern 22 and the third polysilicon pattern 24 formed under the fourth polysilicon pattern 35, a device failure does not occur.

Next, as shown in example FIG. 9, a lightly doped drain (LDD) region 11 is formed in the semiconductor substrate 10. The LDD region 11 may be formed by performing an ion implantation process over the entire surface of the semiconductor substrate 10.

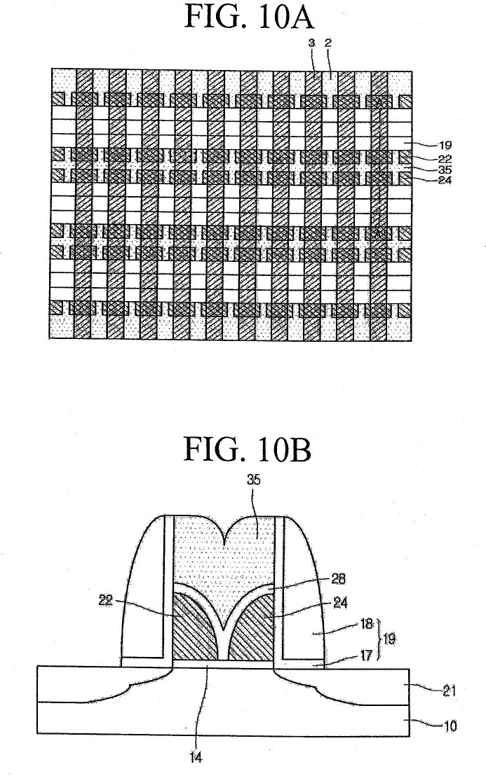

Next, as shown in example FIGS. 10A and 10B, a spacer 19 may be formed over sidewalls of the second, third and fourth polysilicon patterns 22, 24, 35, the tunnel oxide layer pattern 14 and the dielectric pattern 28. Then a source and drain region 21 may be formed. The spacer 19 may be formed as an ON (Oxide-Nitride) structure consisting of a third oxide layer 17 and a second nitride layer 18.

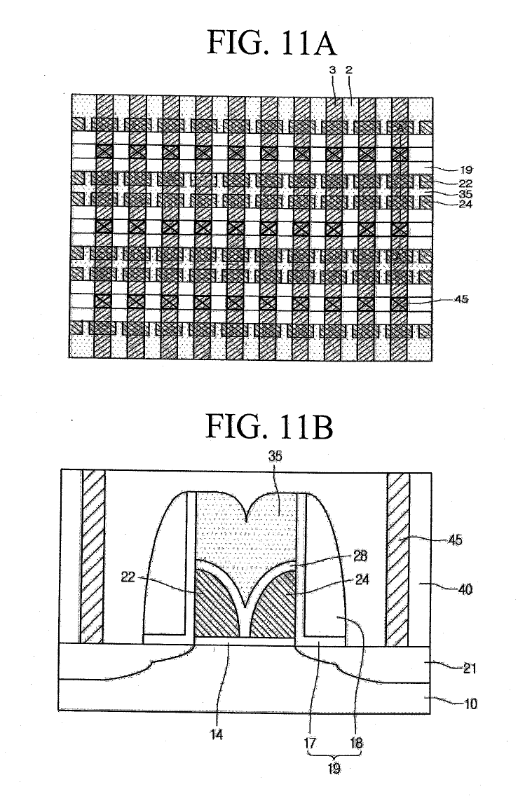

Next, as shown in example FIGS. 11A and 11B, an interlayer insulating layer 40 may be formed over the semiconductor substrate 10. Then a contact 45 connected to the source and drain region 21 may be formed in the interlayer insulating layer 40. Prior to forming the contact 45, a salicide (self-aligned silicide) process may be performed to form a salicide layer over a region where the contact 45 is being formed.

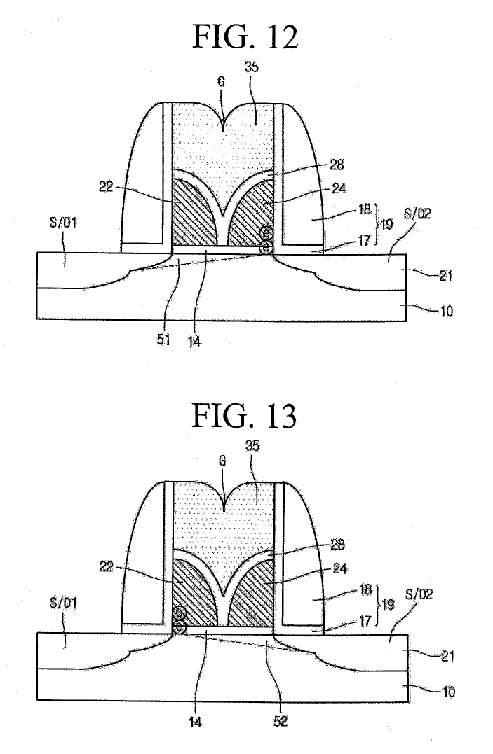

Example FIGS. 12 and 13 are sectional views illustrating operations of the flash memory device manufactured by the above-described method. Each cell may be programmed by a hot carrier injection method. Herein, it is assumed that the third polysilicon pattern 24 is referred to as a first cell and the second polysilicon pattern 22 is referred to as a second cell. When a bias is applied to gate G, depletion of charge in the channel region starts, so that a first inversion region 51 may be formed as shown in example FIG. 12. After the first inversion region 51 is formed, when a bias is applied to a second source/drain contact S/D2, channel pinch off occurs. Hot electrons are injected into the first cell 24 through the tunnel oxide layer pattern 14, and thus the first cell 24 is programmed. When a bias is applied to gate G, depletion of charge in the channel region starts, so that a second inversion region 52 may be formed as shown in example FIG. 13. After the second inversion region 52 is formed, when a bias is applied to a first source/drain contact S/D1, channel pinch off occurs. Hot electrons are injected into the second cell 22 through the tunnel oxide layer pattern 14 and thus the second cell 22 is programmed. At this time, 4 bits may be realized by the first and second cells 24 and 22 as below table 1.

TABLE 1

| | 1^{st} cell | 2^{nd} cell |
|---|---|---|
| 1 bit | Program | Erase |
| 2 bit | Erase | Program |
| 3 bit | Program | Program |
| 4 bit | Erase | Erase |

After the first and second cells 24 and 22 are programmed by a hot carrier injection method, they are erased by Fowler-Nordheim tunneling (F-N tunneling).

Table 2 shows conditions for program and erase.

TABLE 2

| | S/D1 | | S/D2 | | Gate (G) | | Substrate | |
|---|---|---|---|---|---|---|---|---|
| 1^{st} cell program | 0 | V | 3~5 | V | 9 | V | 0 | V |
| 2^{nd} cell program | 3~5 | V | 0 | V | 9 | V | 0 | V |

| | | | | | | |
|---|---|---|---|---|---|---|
| 1^{st} cell erase | 6~8 | V | Floating | −8~−10 | V | Floating |

| | | | | | | |
|---|---|---|---|---|---|---|
| 2^{nd} cell erase | Floating | 6~8 | V | −8~−10 | V | Floating |

Under the above conditions, by exciting or emitting electrons or holes into the first cell 24 and the second cell 22 formed under the fourth polysilicon pattern 35 that is a control gate, a potential barrier in a surface of the semiconductor substrate 10 under the first cell 24 and the second cell 22 may be varied. Thus, by varying the potential barrier in the surface of the semiconductor substrate to control the flow of electrons, a memory device capable of storing 4 bits (00, 01, 10, 11) per cell can be realized. In the method of manufacturing a flash memory device according to embodiments, when a polysilicon layer for forming a control gate is patterned, the control gate may be aligned with the underlying floating gate such that the same bias is applied to the floating gate. Accordingly, in performing an etching for forming the control gate, failures due to misalignments can be decreased, thereby enhancing the device reliability.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate; and then
forming a tunnel oxide layer over the semiconductor substrate; and then
forming a first polysilicon pattern having sidewalls over the tunnel oxide layer; and then
forming a second polysilicon pattern over a sidewall of the first polysilicon pattern; and then
forming a third polysilicon pattern over a sidewall of the first polysilicon pattern; and then
forming a dielectric layer over the first, second and third polysilicon patterns; and then
forming a polysilicon layer over the dielectric layer; and then
performing an etching process to form a tunnel oxide layer pattern, a dielectric pattern, and a fourth polysilicon pattern.

2. The method of claim 1, further comprising forming spacers over sidewalls of the dielectric pattern, the tunnel oxide layer pattern, and the second, third and fourth polysilicon patterns.

3. The method of claim 1, further comprising forming a source and drain region in the semiconductor substrate.

4. The method of claim 1, wherein forming the second and third polysilicon patterns over the sidewall of the first polysilicon pattern comprises:
forming a second polysilicon layer over the tunnel oxide layer over which the first polysilicon pattern is formed; and then
performing an anisotropic etch on the second polysilicon layer.

5. The method of claim 1, wherein the second polysilicon pattern and the third polysilicon pattern are formed at the same time.

6. The method of claim 1, wherein forming the second and the third polysilicon patterns over the sidewall of the first polysilicon pattern comprises exposing the tunnel oxide layer between the second polysilicon pattern and the third polysilicon pattern.

7. The method of claim 1, wherein after the performing of the etching process, the fourth polysilicon pattern is aligned with the tunnel oxide layer pattern over which the second and third polysilicon patterns are formed.

8. The method of claim 1, wherein forming the dielectric layer comprises contacting the dielectric layer with the tunnel oxide layer exposed between the second polysilicon pattern and the third polysilicon pattern.

9. The method of claim 1, wherein the tunnel oxide layer is formed by a thermal oxidation process.

10. The method of claim 1, wherein when a bias is applied to the fourth polysilicon pattern, the same bias as the bias applied to the fourth polysilicon pattern is applied to the underlying second and third polysilicon patterns.

11. The method of claim 1, wherein the dielectric pattern is disposed between the second polysilicon pattern and the third polysilicon pattern such that the second polysilicon pattern and the third polysilicon pattern are separated by the dielectric pattern.

12. The method of claim 1, wherein the dielectric layer is formed of an oxide-nitride-oxide layer.

13. The method of claim 1, wherein the dielectric layer is formed of an oxide-nitride layer.

14. An apparatus comprising:
a semiconductor substrate;
a tunnel oxide layer pattern over the semiconductor substrate;
a first polysilicon pattern having sidewalls over the tunnel oxide layer pattern;
a second polysilicon pattern over a sidewall of the first polysilicon pattern;
a third polysilicon pattern over a sidewall of the first polysilicon pattern;
a dielectric pattern over the first, second and third polysilicon patterns; and
a fourth polysilicon pattern over the dielectric pattern.

15. The apparatus of claim 14, further comprising spacers formed over sidewalls of the dielectric pattern, the tunnel oxide layer pattern, and the second, third and fourth polysilicon patterns.

16. The apparatus of claim 14, wherein the dielectric pattern is disposed between the second polysilicon pattern and the third polysilicon pattern such that the second polysilicon pattern and the third polysilicon pattern are separated by the dielectric pattern.

17. The apparatus of claim 14, further comprising a source and drain region formed in the semiconductor substrate.

18. The apparatus of claim 14, wherein the fourth polysilicon pattern is aligned with the tunnel oxide layer pattern over which the second and third polysilicon patterns are formed.

19. The apparatus of claim 14, wherein the dielectric pattern is formed of an oxide-nitride-oxide layer.

20. The apparatus of claim 14, wherein the dielectric pattern is formed of an oxide-nitride layer.
